(19) United States
(12) Patent Application Publication
(10) Pub. No.: US 2015/0111370 A1
(43) Pub. Date: Apr. 23, 2015

(54) CRACK-FREE GALLIUM NITRIDE MATERIALS

(71) Applicant: Nanogan Limited, Bath (GB)

(72) Inventor: Wang Nang Wang, Bath (GB)

(21) Appl. No.: 14/517,735

(22) Filed: Oct. 17, 2014

(30) Foreign Application Priority Data
Oct. 17, 2013 (GB) GB1318420.5

(51) Int. Cl. H01L 21/02

(52) U.S. Cl. CPC H01L 21/02458; H01L 21/0243; H01L 21/02381; H01L 21/02491; H01L 21/0254
USPC 438/478; 428/610

(57) ABSTRACT

A method for producing gallium nitride material, comprising the steps of:
a) providing a substrate and forming a metal layer over the substrate;
b) forming a transition layer over the metal layer, the transition layer being compositionally graded such that the composition of the transition layer at a depth (z) thereof is an Al concentration function f(z) of that depth; and
c) forming a layer of gallium nitride material over the transition layer;
   wherein the Al compositional grading function f(z) of the transition layer grown in step b) has a profile including two plateaux at respective depths z1 and z2 where df(z1)/dz=df(z2)/dz=0, wherein the function decreases continuously between z1 and z2 with z2>z1.

### CROSS-REFERENCE TO RELATED APPLICATION

This application claims priority to and the benefit of GB Application No. GB1318420.5, filed Oct. 17, 2013. The entire contents of all of these are incorporated herein by reference.

### FIELD OF THE INVENTION

This invention relates to methods for producing gallium nitride materials, and semiconductor templates for producing gallium nitride materials.

### BACKGROUND OF THE INVENTION

Gallium nitride materials are semiconductor compound materials that are typically grown on a substrate, for example silicon (Si), sapphire or silicon carbide. Common examples of gallium nitride materials include gallium nitride (GaN) and the alloys indium gallium nitride (InGaN), aluminium gallium nitride (AlGaN) and aluminium indium gallium nitride (AlInGaN).

In typical growth processes, layers of the GaN are successively deposited onto the substrate. There is a problem however that in many cases, the GaN will have a different thermal expansion co-efficient than the substrate. This may lead to cracking of the GaN during cooling, especially where the nitride layer is relatively thick. A further problem arises since the lattice constants of GaN and the substrate are usually different, i.e. mismatched, which can lead to defect formation in the deposited GaN layers.

It has been proposed to address these problems by the inclusion of at least one intermediate layer between the substrate and the subsequently deposited GaN, i.e. forming a semiconductor template comprising a substrate and an additional layer formed over the substrate, over which the GaN may be formed.

### SUMMARY OF THE INVENTION

In the particular case of silicon substrates, which exhibit particularly large differences in both thermal expansion co-efficient and lattice constant to GaN, it has been proposed to use intermediate transition layers of graded composition between the silicon and the GaN, and this is schematically shown in FIG. 1. For example, it has been proposed to use a AlInGaN alloy as the transition layer 1, which is compositionally graded so that the Gallium concentration is highest at the top of the layer, i.e. nearest to the subsequently deposited GaN 2, and lowest at the bottom of the layer, which would be nearest to the silicon substrate 3. Such techniques have been found to reduce internal stresses within the structure, since the lattice constant and thermal expansion co-efficient of the graded transition layer is close to that of the GaN at the top surface, and relatively close to the silicon at the bottom surface. It should be noted that various materials can be used for the transition layer or layers, as long as certain lattice match and thermal expansion co-efficient matching is provided. In alternative structures, such graded intermediate layers may be included with one or more non-graded buffer layers between the substrate and GaN, and an example is schematically shown in FIG. 2, which shows a single non-graded buffer layer 4 between substrate 3 and graded transition layer 1.

There are two general types of grading employed within the transition layer: a “continuous” grading, in which the concentration of gallium (for the sake of example) increases smoothly from the bottom to the top of the layer, and “discontinuous” grading, in which the concentration increases in a step-wise manner from the bottom to the top of the layer. FIGS. 3a-3e schematically show various grading schemes proposed, the x-axis being thickness of the transition layer, with the y-axis showing the concentration of gallium, with FIGS. 3a, 3b and 3c respectively showing three possible continuous grading schemes, while FIGS. 3d and 3e show two discontinuous schemes.

However, both the continuous and discontinuous techniques have disadvantages. With discontinuous schemes, at the point of discontinuity, there is a large lattice mismatch, which can lead to defect formation from the interface and extended to the overgrown AlGaN. With continuous schemes, the effect of strain engineering—particularly in introducing the compressive strain is much more difficult to achieve. The gradient profile of the continuously graded layer is very difficult to control due to the binding energy and gas phase reaction of Al and Ga with NH₃. The Ga concentration increases exponentially in the initial stage of linear GaN concentration ramping, and leave the later stage of Ga profile nearly flat. This phenomenon is particularly pronounced for the concentration difference of the initial and final Ga exceeding 30%.

It has also been proposed to use superlattice structures to reduce internal stresses. As is well-known in the art, a superlattice is a periodic structure of layers of at least two materials, typically each layer being in the nanometer scale of thickness. FIG. 4 schematically shows a known structure employing a strained-layer superlattice 5 as an intermediate, compositionally-graded, transition layer between substrate 3 and GaN 2. Superlattice 5 comprises a plurality of layers 6 of semiconductor compounds. Alternate layers are formed from differently composed compounds, such as AlₓIn_{y}Ga_{(1-x-y)}N and AlₐIn_{b}Ga_{(1-a-b)}N respectively, wherein x<a and y<b. Each layer 6 may itself be compositionally-graded, or alternatively each layer 6 may be non-compositionally-graded but adjacent layers are of different composition (e.g. with differing concentrations of Al in each layer 6), to form a composite graded structure.

A problem with this superlattice technique is the initial strain is retained and the strain engineering effect of introducing compressive strain is limited.

As prior art may be mentioned U.S. Pat. No. 6,659,287 and its continuation U.S. Pat. No. 6,617,060 which disclose various continuous and discontinuous GaN layering schemes, including use of discontinuous superlattices. Its claim 1 for example is directed to a semiconductor material comprising: a silicon substrate; an intermediate layer comprising aluminium nitride, an aluminium nitride alloy, or a gallium nitride alloy formed directly on the substrate; a compositionally-graded transition layer formed over the intermediate layer; and a gallium nitride material layer formed over the transition layer, wherein the semiconductor material forms a FET. Its claim 2 meanwhile is directed to the semiconductor material of claim 1, wherein the composition of the transition layer is graded discontinuously across the thickness of the layer.

As other prior art may be mentioned US 20020020341 which discloses the use of continuous-grade GaN layering. Its claim 1 for example is directed to a semiconductor film, comprising: a substrate; and a graded gallium nitride layer deposited on the substrate having a varying composition of a substantially continuous grade from an initial composition to a final composition formed from a supply of at least one precursor in a growth chamber without any interruption in the supply.

It is an aim of the present invention to overcome the problems noted above, and to provide improved methods for forming gallium nitride materials. This aim is achieved by using transition layers in various controlled schemes.

In accordance with a first aspect of the present invention there is provided a method for producing gallium nitride material, comprising the steps of:
a) providing a substrate and forming a metal layer over the substrate;
b) forming a transition layer over the metal layer, the transition layer being compositionally graded such that the composition of the transition layer at a depth (z) thereof is an Al concentration function f(z) of that depth; and
c) forming a layer of gallium nitride material over the transition layer;
   wherein the Al compositional grading function f(z) of the transition layer grown in step b) has a profile including two plateaux at respective depths z1 and z2 where df(z1)/dz=df(z2)/dz=0, wherein the function decreases continuously between z1 and z2 with z2>z1.

The Al concentration difference between the two plateaux may be less than or equal to 30% of the Al concentration at depth z1.

The Al concentration difference between the two plateaux may be less than or equal to 30% of the Al concentration at depth z2.

The compositional grading function f(z) may include at least one additional plateau at a respective depth zn where df(zn)/dz=0.

Between depths z1 and z2 the Al concentration function f(z) may decrease linearly.

Between depths z1 and z2 the Al concentration function f(z) may decrease non-linearly.

The method may further comprise the step of forming a buffer layer between the substrate and the transition layer.

The method may further comprise the step of forming a buffer layer between the transition layer and the gallium nitride material layer.

The transition layer may comprise a superlattice.

With the stepwise semi-continuous transition and maintaining the concentration difference between two neighbouring plateau less or equal to 30%, there is no abrupt interface to introduce the interface lattice mismatch related defects, and the gradient profile of the continuously decreasing region is much more easy to control with better strain engineering effect.

The metal layer may comprises Al.

The thickness of metal layer may be in the range from 1-2 monolayers.

The method may further comprise the step, intermediate steps a) and b), of forming an AlN layer over the substrate.

The AlN layer may be formed over the metal layer.

The substrate may comprise silicon.

In accordance with a second aspect of the present invention there is provided a method for producing gallium nitride material, comprising the steps of:
a) providing a substrate and forming a metal layer over the substrate;
b) forming a superlattice transition layer over the substrate, the superlattice transition layer consisting of at least one pair of layers of AlxInyGa(1-x-y)N(0<x<=1), each layer pair comprising a first layer and a second layer, the second layer having a greater thickness and lower Al concentration than the first layer; and
c) forming a layer of gallium nitride material over the superlattice transition layer.

The method may further comprise the step, intermediate steps a) and b), of forming an AlₓGa₍₁₋ₓ₎N layer with 0.1<x<0.9 over the substrate, and wherein in step b) the superlattice transition layer is formed over the AlₓGa₍₁₋ₓ₎N layer.

Step b) may be repeated at least once.

Steps b) and c) may be repeated at least once.

The method may further comprise the step of forming a buffer layer between the substrate and the superlattice transition layer.

The method may further comprise the step of forming a buffer layer between the superlattice transition layer and the gallium nitride material layer.

The metal layer may comprise Al.

The thickness of metal layer may be in the range from 1-2 monolayers.

The method may further comprise the step, intermediate steps a) and b), of forming an AlN layer over the substrate.

The AlN layer may be formed over the metal layer.

The substrate may comprise silicon.

In accordance with a third aspect of the present invention there is provided a method for producing gallium nitride material, comprising the steps of:
a) providing a substrate and forming a metal layer over the substrate;
b) forming a superlattice transition layer over the substrate, the superlattice transition layer consisting of at least two pairs of layers of AlxInyGa(1-x-y)N(0<x<=1), each layer pair comprising a first layer and a second layer, the second layer having a greater thickness and lower Al concentration than the first layer, and
c) forming a layer of gallium nitride material over the superlattice transition layer;
   wherein in step b), the Al concentration of the of each layer within each pair is constant, and the thickness of the lower Al concentration layer within each pair is progressively increased in successively formed pairs such that the average Al composition of each pair in the superlattice transition layer decreases continuously, to produce a compositional gradient throughout the superlattice transition layer.

Step b) may be repeated at least once.

Steps b) and c) may be repeated at least once.

The method may further comprise the step, intermediate steps a) and b), of forming an AlₓGa₍₁₋ₓ₎N layer with 0.1<x<0.9 over the substrate, and wherein in step b) the superlattice transition layer is formed over the AlₓGa₍₁₋ₓ₎N layer.

The metal layer may comprise Al.

The thickness of metal layer may be in the range from 1-2 monolayers.

The method may further comprise the step, intermediate steps a) and b), of forming an AlN layer over the substrate.

The AlN layer may be formed over the metal layer.

The substrate may comprise silicon.

In accordance with a fourth aspect of the present invention there is provided a method for producing gallium nitride material, comprising the steps of:
a) providing a substrate and forming a metal layer over the substrate;
b) forming a first transition layer over the substrate;
c) forming a layer of GaN over the first transition layer;
d) forming at least one subsequent transition layer over the first transition layer, each subsequent transition layer being formed at a higher temperature than the previous transition layer; and
e) forming a layer of gallium nitride material over a subsequent transition layer.

One of the transition layers may comprise AlGaN.

One of the transition layers may comprise SiN.

Steps d) and e) may be repeated at least once.

The metal layer may comprise Al.

The thickness of metal layer may be in the range from 1-2 monolayers.

The method may further comprise the step, intermediate steps a) and b), of forming an AlN layer over the substrate.

The AlN layer may be formed over the metal layer.

The substrate may comprise silicon.

In accordance with a fifth aspect of the present invention there is provided a method for producing gallium nitride material, comprising the steps of:
a) providing a substrate and forming a metal layer over the substrate;
b) forming a first transition layer over the substrate;
c) forming a GaN layer over the first transition layer;
d) forming a second transition layer over the GaN layer; and
e) forming a layer of gallium nitride material over the second transition layer;
   wherein one of said first and second transition layers comprises AlGaN and the other of said first and second transition layers comprises SiN.

Step d) may be repeated at least once.

Steps d) and e) may be repeated at least once.

Step d) may comprise forming at least two additional transition layers, such that transition layers of AlGaN and SiN are alternately formed.

Each transition layer may be formed at a higher temperature than the previous transition layer.

The transition layers may comprise a superlattice.

The method may further comprise the step of forming a buffer layer between the substrate and the first transition layer.

The method may further comprise the step of forming a buffer layer between the second transition layer and the gallium nitride material layer.

The metal layer may comprise Al.

The thickness of metal layer may be in the range from 1-2 monolayers.

The method may further comprise the step, intermediate steps a) and b), of forming an AlN layer over the substrate.

The AlN layer may be formed over the metal layer.

The substrate may comprise silicon.

In accordance with a sixth aspect of the present invention there is provided a method for producing a substrate material, the method comprising the steps of:
a) providing a substrate material wafer;
b) treating the wafer with laser application to create an etching pattern located within the wafer, the pattern being such as to cause bowing of the wafer.

The laser treatment may comprise stealth laser treatment.

The bowing may be concave.

The bowing may be convex.

The substrate may comprise silicon.

In accordance with a seventh aspect of the present invention there is provided a semiconductor template for producing a gallium nitride material, comprising a substrate with a metal layer formed over the substrate, and a transition layer formed over the substrate, the transition layer being compositionally graded such that the composition of the transition layer at a depth (z) thereof is a function f(z) of that depth;

wherein the Al compositional grading function f(z) of the transition layer has a profile including two plateaux at respective depths z1 and z2 where df(z1)/dz=df(z2)/dz=0, and wherein the function decreases continuously between z1 and z2.

In accordance with a eighth aspect of the present invention there is provided a semiconductor template for producing a gallium nitride material, comprising a substrate with a metal layer formed over the substrate, and a superlattice transition layer formed over the substrate, the superlattice transition layer being compositionally graded such that the Al composition of the superlattice transition layer at a depth (z) thereof is a function f(z) of that depth;

wherein the Al compositional grading function f(z) of the superlattice transition layer decreases continuously throughout the thickness of the superlattice transition layer.

In accordance with an ninth aspect of the present invention there is provided a semiconductor template for producing a gallium nitride material, comprising a substrate with a metal layer formed over the substrate, a first transition layer formed over the substrate and a second transition layer formed over the first transition layer, wherein the second transition layer is formed at a higher temperature than the first transition layer.

In accordance with a tenth aspect of the present invention there is provided a 45. A semiconductor template for producing a gallium nitride material, comprising a substrate with a metal layer formed over the substrate, with a layer of AlGaN and a layer of SiN formed over the substrate.

The substrate may comprise silicon.

Other aspects of the present invention are as set out in the accompanying claims.

### BRIEF DESCRIPTION OF THE DRAWINGS

The invention will now be described with reference to the accompanying drawings, in which:

FIG. 1 schematically shows a prior art semiconductor structure including a silicon substrate, intermediate layer and GaN top layer;

FIG. 2 schematically shows a prior art semiconductor structure similar to that of FIG. 1, but including a buffer layer;

FIGS. 3a-3e schematically show known grading schemes for an insertion layer, with FIGS. 3a, 3b and 3c respectively showing three possible continuous grading schemes, while FIGS. 3d and 3e show two discontinuous schemes;

FIG. 4 schematically shows a known superlattice semiconductor structure;

FIGS. 5a, 5b and 5c schematically show semi-continuous grading schemes according to respective embodiments of the present invention;

FIGS. 6a to 9 schematically show cross-sectional views of exemplary structures formed in accordance with aspects of the present invention; and

FIGS. 10a and 10b schematically show a laser treated substrate in plan and sectional views respectively, including a convex bowing.

### DETAILED DESCRIPTION OF EMBODIMENTS

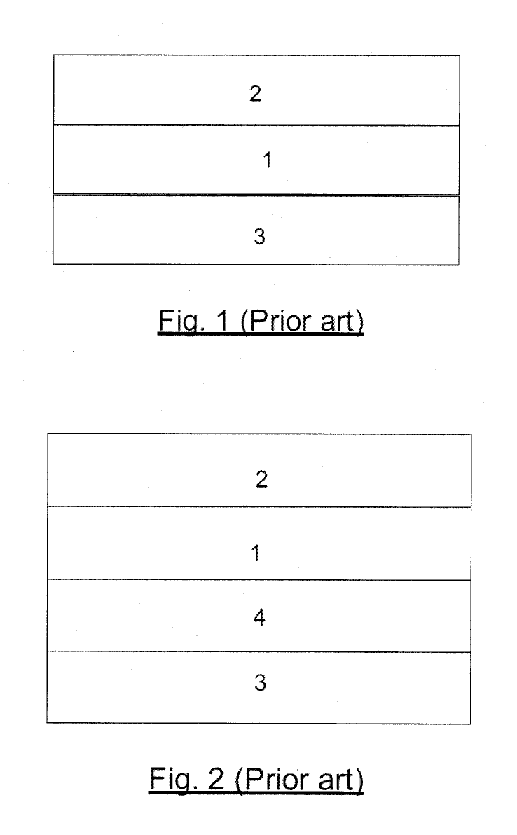

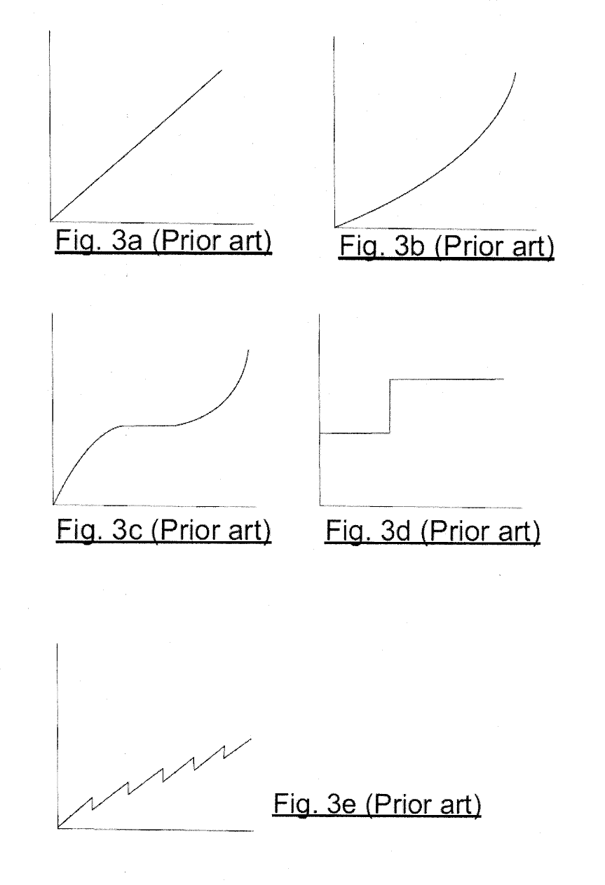

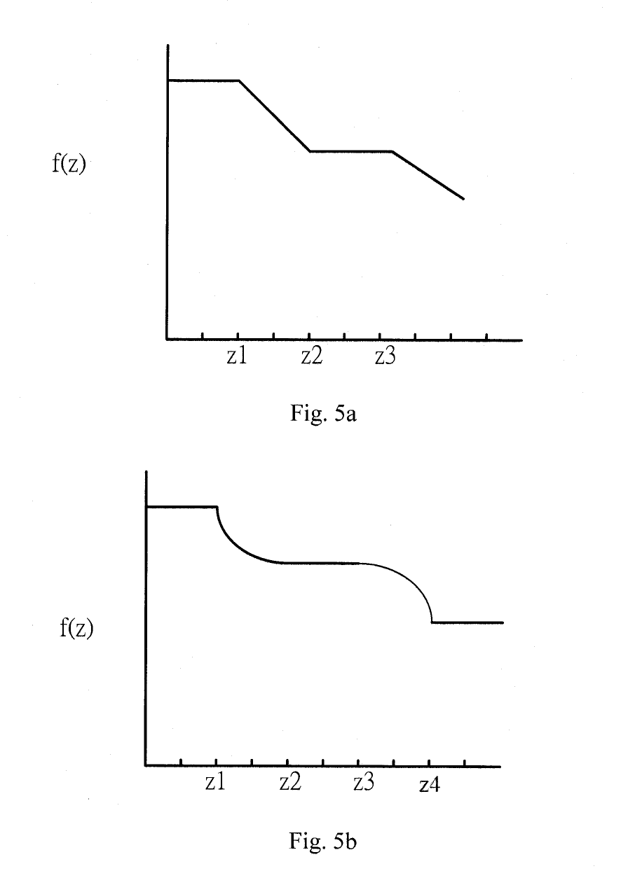

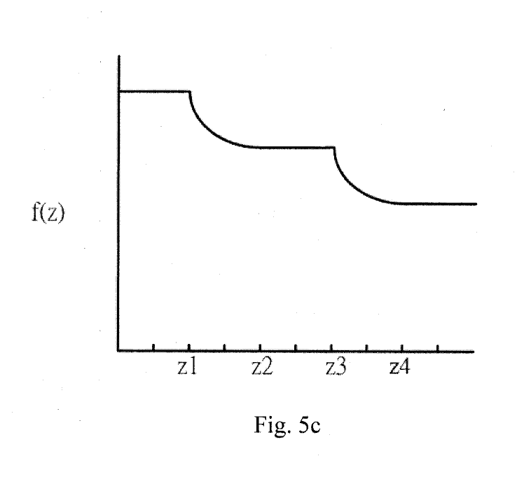

In a first embodiment, gallium nitride material is produced using a structure similar to that shown in FIG. 1. However, in accordance with an aspect of the present invention, the compositional grading scheme used for the transition layer follows a “hybrid” or “semi-continuous” scheme, as shown in FIG. 5.

In more detail, a transition layer comprising AlGaN for example is formed over the substrate, and is compositionally graded such that the composition of the transition layer at a depth (z) thereof is a function f(z) of that depth, wherein the Al compositional grading function f(z) of the transition layer grown in step b) has a profile including at least two plateaux at respective depths z1 and z2 where df(z1)/dz=df(z2)/dz=0, and wherein the function increases continuously between z1 and z2. In fact, FIGS. 5a and 5b both show more than two plateaux, with a third plateau z3 also being shown.

FIG. 5a shows an example where the grading function f(z) varies linearly between depths z1 and z2. FIG. 5b meanwhile shows an alternative exemplary embodiment where f(z) varies non-linearly between depths z1 and z2. In fact, in FIG. 5b, between z1 and z2, df(z)/dz decreases from z1 to z2 (concave curve), while from z=z3 to z4, df(z)/dz decreases (convex curve). Any combination of linear or non-linear continuous decreases may be employed. FIG. 5c for example shows a scheme in which there are only concave decrease curves between z1 and z2, from z3 to z4.

Conveniently, the grading function may indicate the concentration of aluminium at each depth (z) of the transition layer. Although aluminium is particularly suitable, the concentration of other substances may alternatively be so varied.

### Example 1

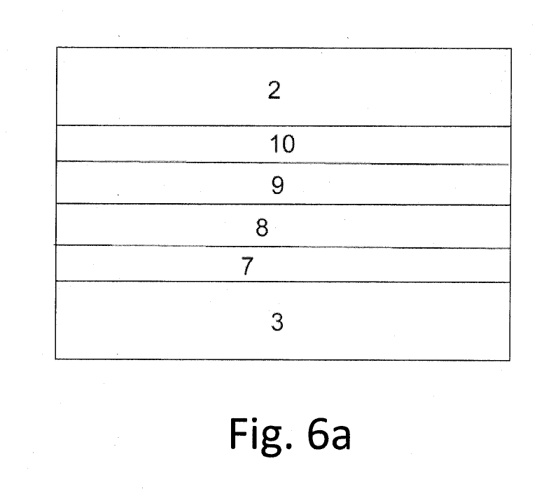

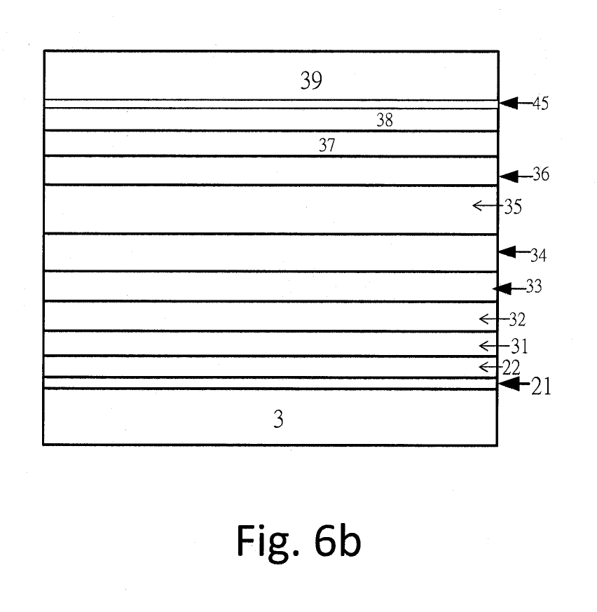

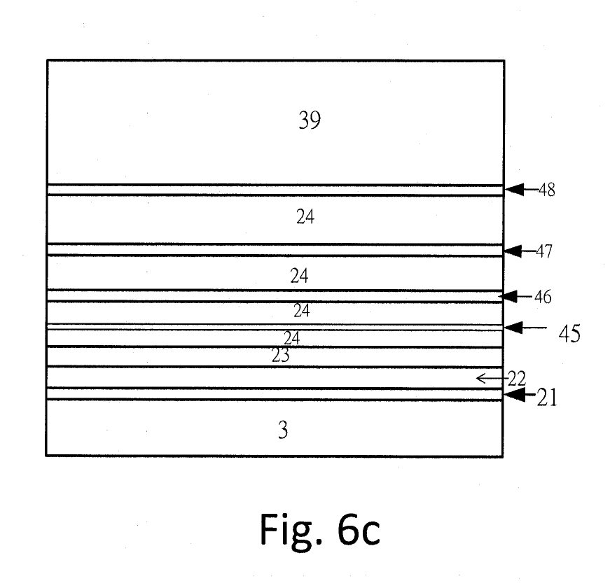

In a first embodiment, shown in FIG. 6a, a semiconductor template comprising a substrate 3 and a number of transition layers 7-10 formed over the substrate is used to produce a GaN material layer 2. Here, a first transition layer 7 is formed over the substrate 3 at a first temperature, a second transition layer 8 is formed over the first transition layer 7 at a higher temperature, and subsequent transition layers 9 and 10 are also formed at successively higher temperatures.

This method reduces dislocation density in both XRC (X-Ray Crystallography) (102) and (002) axes.

The transition layers could comprise AlGaN for example, or, similarly to the embodiment below, may comprise AlGaN and SiN in alternate, paired, layers.

### Example 2

This example relates to that shown in FIG. 6b. A (111) Silicon substrate of about 2, 4, 6 or 8 inches in diameter is loaded in the MOCVD. A thin metal layer 21, in this case of Al, is deposited for about 10 seconds after the thermal desorption at 1050° C. under H2. The thickness of the Al is only around 1-2 monolayers. The coverage of the Al prevents the Melt etch back of Si by NH3. The Al growth is followed by the deposition of undoped AlN of 20-200 nm 22. Then multiple transitional layers of AlxGal-xN are grown. A first transitional layer 31 is grown with a thickness of around 20-200 nm and an Al concentration gradient from 100% Al to 80% Al. A layer 32 of Al0.80Ga0.2N is then grown. Then layer 33 is grown with an Al concentration gradient decreasing to 55% Al, then a layer 34 of Al0.55Ga0.45N of 50-250 nm is grown. Then layer 35 is grown with an Al concentration gradient decreasing to 25% Al, then a layer 36 of Al0.25Ga0.75N of 50-300 nm is grown, then a layer 37 is grown with an Al concentration gradient decreasing to 0% Al, followed by a layer 38 of GaN of thickness around 50-750 nm. A thin Si3N4 layer 45 of around 5-10 nm is then grown followed by growth of a layer 39 of n-GaN of thickness around 1 to 4 μm. This GaN is grown in a three step growth process. The first step is with medium low temperature (950-1020° C.) and high pressure (300 mbar to ATM) for 3D growth, then the temperature is raised by about 50-100° C. and the pressure is set to be medium around 200-500 mbar) for 3D to 2D GaN growth, then the pressure is reduced to around 50-200 mbar and temperature raised to around 102-1150° C. for fast 2D GaN growth. The epitaxial growth of the full device is continued in the MOCVD reactor. A typical LED structure formed comprises the following layers: InGaN/GaN MQW active region (30 Å/120 Å, 2-8 pairs), AlGaN:Mg capping layer (˜200 Å), p-type Mg-doped GaN (0.1-0.3 μm). The electron and hole concentration in the GaN:Si and GaN:Mg layers are about 8×10¹⁸ cm³ and 8×10¹⁷ cm³, respectively.

In a modification of this embodiment (not shown), a (111) Silicon substrate of about 2, 4, 6 or 8 inches in diameter is loaded in the MOCVD. A thin Al layer is deposited for about 10 seconds after the thermal desorption at 1050° C. under H2, followed by the deposition of undoped AlN of 20-200 nm. Then an Al0.25Ga0.75N layer is deposited. The first transitional is grown with the Al0.9Ga0.1N of thickness around 15 nm plus a thin Si3N4 layer, then a GaN layer of around 0.5 to 0.75 urn is grown, and the transitional layer process is repeated three times. Finally a layer of n-GaN of thickness around 1 to 4 μm is grown. The epitaxial growth of the full device is continued in the MOCVD reactor. A typical LED structure formed comprises the following layers: InGaN/GaN MQW active region (30 Å/120 Å, 2-8 pairs), AlGaN:Mg capping layer (˜200 Å), p-type Mg-doped GaN (0.1-0.3 μm). The electron and hole concentration in the GaN:Si and GaN:Mg layers are about 8×10¹⁸ cm⁻³ and 8×10¹⁷ cm⁻³, respectively.

### Example 3

FIG. 6c shows a further example, in which the process is similar to that of Example 2, except that an extra AlxGal-xN layer 23 with 0.1<x<=0.3 is grown on top of the MN, then followed by the growth of a layer 24 of GaN and a layer 45 of SiN with a further GaN layer 24 on top of that. Multiple transitional layers 46 (followed by a further GaN layer 24), 47 (followed by a further GaN layer 24), and 48 of AlxGal-xN with 0.1<x<1, are then successively grown, with each layer grown at a different temperature. In this example layers 46, 47, and 48 are grown at 850, 890 and 9.40° C. respectively. A final layer 39 of GaN is then grown.

### Example 4

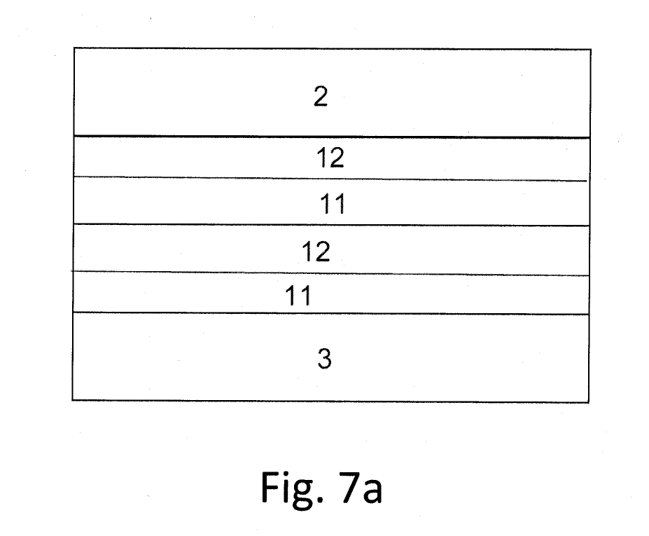

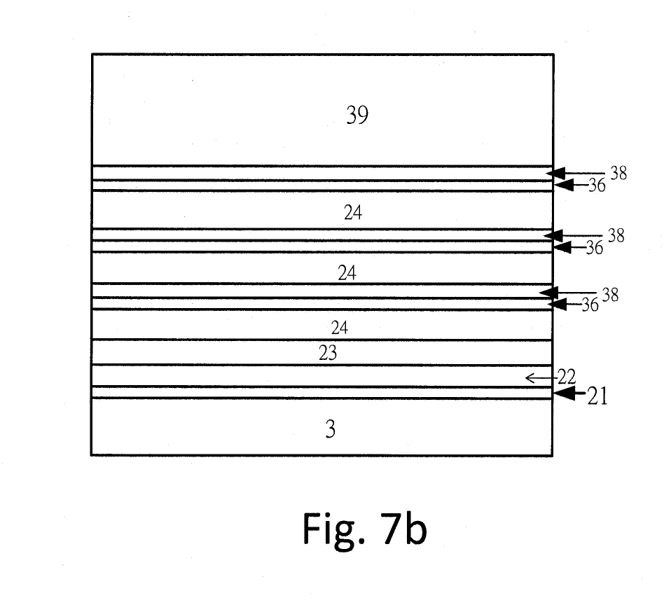

In a further embodiment, shown in FIG. 7a, a semiconductor template comprising a substrate 3 and at least two transition layers formed over the substrate is used to produce a GaN material layer 2. Here, alternate paired transition layers of AlGaN 11 and SiN 12 are formed over the substrate 3. These layers could be in either order, i.e. so that SiN layer 12 may be formed proximate substrate 3, rather than AlGaN layer 11 as shown in FIG. 7a.

As in the previous embodiment, successive transition layers could be formed at successively higher temperatures.

### Example 5

FIG. 7b shows a further example. Here, the process is similar to that of Example 2 except that a layer 23 of AlGaN 25% is grown on top of the layer 22 of AlN. A layer 24 of GaN is grown followed by multiple transitional layers comprising a pair of alternating AlGaN layer 36 with Al>=50% and SiNx layer 38 of thickness less than 10 nm. Following growth of each such pair, a further GaN layer 24 is grown, followed by another transitional layer pair. In total, there are three sets of GaN layer plus associated paired transitional layers.

The transition layer here may optionally comprise a superlattice.

### Example 6

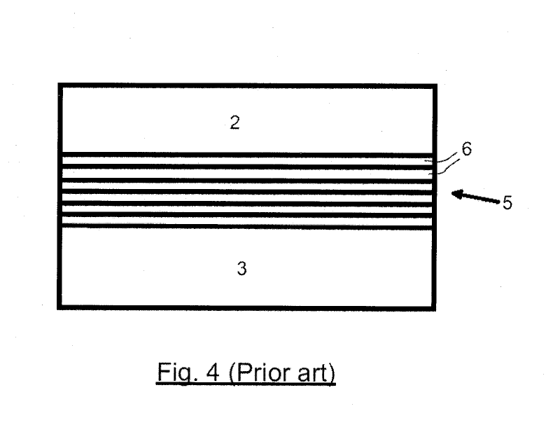

In another embodiment, a template structure generally similar to that of FIG. 4 is used, i.e. so that a superlattice transition layer is formed over a substrate, the superlattice transition layer being compositionally graded such that the composition of the superlattice transition layer at a depth (z) thereof is a function f(z) of that depth. A layer of gallium nitride material may then be formed over the superlattice transition layer. Unlike the known structure of FIG. 4 however, in accordance with the present invention the Al compositional grading function f(z) of the superlattice transition layer decreases continuously throughout the thickness of the superlattice transition layer. The use of a continuous profile prevents lattice mismatch and hence defect formation.

The grading function f(z) may decrease linearly or non-linearly throughout the thickness of the superlattice transition layer as appropriate.

### Example 7

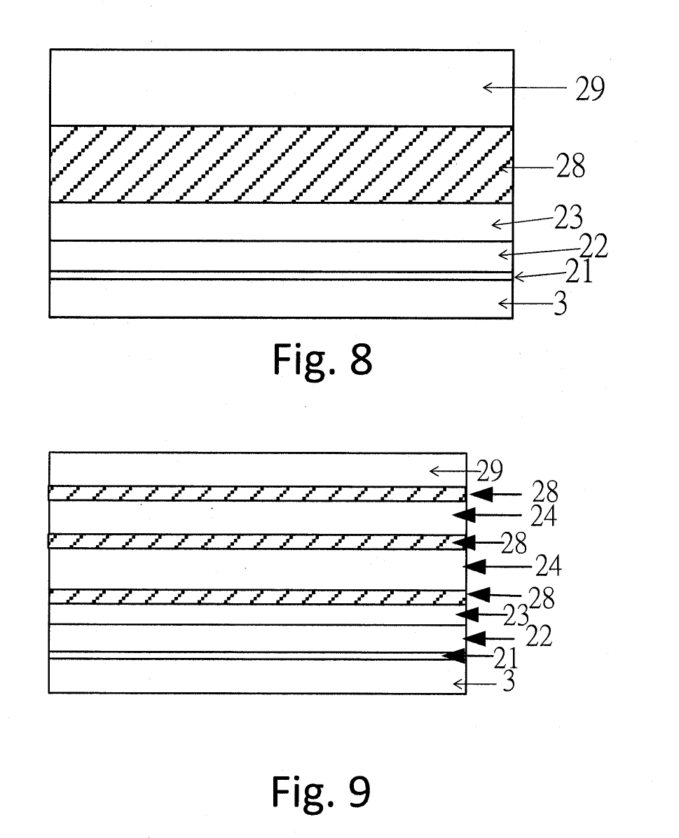

FIG. 8 shows a further example, where a layer of Al 21 is grown onto substrate 3, a layer 22 of AlN is grown onto layer 21, a layer 23 of AlGaN is grown onto layer 22 and then a transitional layer 28 is grown thereon, layer 28 comprising AlN/GaN superlattices of AlN of thickness 3 nm and GaN, whose thickness increases continuously from 4 to 15 nm. A layer 29 of GaN is then grown over layer 28. The thickness of superlattice layer 28 is around 100 to 3500 nm.

### Example 8

FIG. 9 shows a further example where the process is similar to that of Example 7 except that here there are multiple transitional layers, which comprise the AlN/GaN superlattices 28 of AlN of thickness 3 nm and GaN of continuously increasing thickness from 4-15 nm, interlayered with layers of GaN 24. A layer 29 of GaN is grown onto the final superlattice layer 28. The superlattice thickness of each transitional layer is around 50 to 500 nm.

### Example 9

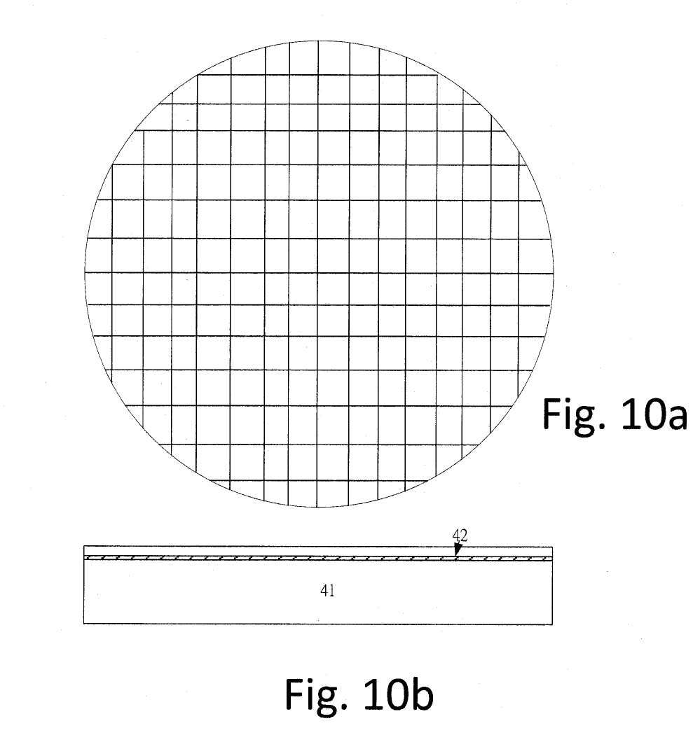

FIGS. 10a and 10b show a further embodiment a six inch (for the sake of example only) silicon (111) substrate 41 of about 1000 um thickness is pre-treated with 942 nm laser beam application to create a pattern within the substrate to cause the substrate to bend, creating a convex “bow” having a displacement depth of around 10-35 um. The laser ablated patterned area 42 is located inside the wafer at a depth of approximately 125 um. The pattern used is a square pattern of 1×1 mm gap between each laser scribe.

Such a bowed substrate may for example be used to benefit subsequent MOCVD growth processes. The temperature of the bottom of the wafer during the heating up is always higher than the top surface, particularly with fast and high power heating to around 1000° C. (such as with GaN growth). This tends to cause a concave bowing in the wafer, which causes an uneven deposition thickness on the surface. However, with a pre-formed convex bow obtained using this laser process, during the heating up, the subsequent bending causes the wafer to flatten out for better uniform deposition.

The above-described embodiments are exemplary only, and other possibilities and alternatives within the scope of the invention will be apparent to those skilled in the art. For example, with any of the schemes or structures outlined above, one or more buffer layers may be provided, for example between the substrate and lower transition layer, or between the upper transition layer and the grown gallium nitride materials layer.

In general, use of silane doping will increase the tensile stress quite significantly. However a three step growth process as described above provides a significant improvement in the tensile stress gradient produced by silane doping. The transition layer or layers may optionally be doped with silane or carbon for the purpose of forming full devices. In this case, it has been found that silane doping concentrations of up to about 6×10¹⁸/cm³ can maintain a reasonable compressive stress even with a single transition layer thickness of over 4 μm.

What is claimed is:

1. A method for producing gallium nitride material, comprising the steps of:
a) providing a substrate and forming a metal layer over the substrate;
b) forming a transition layer over the metal layer, the transition layer being compositionally graded such that the composition of the transition layer at a depth (z) thereof is an Al concentration function f(z) of that depth; and
c) forming a layer of gallium nitride material over the transition layer;
wherein the AI compositional grading function f(z) of the transition layer grown in step b) has a profile including two plateaux at respective depths z1 and z2 where df(z1)/dz=df(z2)/dz=0, wherein the function decreases continuously between z1 and z2 with z2>z1.

2. A method according to claim 1, wherein the Al concentration difference between the two plateaux is less than or equal to 30% of the Al concentration at depth z1.

3. A method according to claim 1, wherein the Al concentration difference between the two plateaux is less than or equal to 30% of the Al concentration at depth z2.

4. A method according to claim 1, wherein the compositional grading function f(z) includes at least one additional plateau at a respective depth zn where df(zn)/dz=0.

5. A method according to claim 1, wherein between depths z1 and z2 the Al concentration function f(z) decreases linearly.

6. A method according to claim 1, wherein between depths z1 and z2 the Al concentration function f(z) decreases non-linearly.

7. A method according to claim 1, further comprising the step of forming a buffer layer between the substrate and the transition layer.

8. A method according to claim 1, further comprising the step of forming a buffer layer between the transition layer and the gallium nitride material layer.

9. A method according to claim 1, wherein the transition layer comprises a superlattice.

10. A method for producing gallium nitride material, comprising the steps of:
a) providing a substrate and forming a metal layer over the substrate;
b) forming a superlattice transition layer over the substrate, the superlattice transition layer consisting of at least one pair of layers of AlₓIn_{y}Ga_{(1-x-y)}N(0<x<=1), each layer pair comprising a first layer and a second layer, the second layer having a greater thickness and lower Al concentration than the first layer; and
c) forming a layer of gallium nitride material over the superlattice transition layer.

11. A method according to claim 10, further comprising the step, intermediate steps a) and b), of forming an AlₓGa₍₁₋ₓ₎N layer with 0.1<x<0.9 over the substrate, and wherein in step b) the superlattice transition layer is formed over the AlₓGa₍₁₋ₓ₎N layer.

12. A method according to claim 10, wherein step b) is repeated at least once.

13. A method according to claim 10, wherein steps b) and c) are repeated at least once.

14. A method according to claim 10, further comprising the step of forming a buffer layer between the substrate and the superlattice transition layer.

15. A method according to claim 10, further comprising the step of forming a buffer layer between the superlattice transition layer and the gallium nitride material layer.

16. A method for producing gallium nitride material, comprising the steps of:
a) providing a substrate and forming a metal layer over the substrate;
b) forming a first transition layer over the substrate;
c) forming a layer of GaN over the first transition layer;
d) forming at least one subsequent transition layer over the first transition layer, each subsequent transition layer being formed at a higher temperature than the previous transition layer; and
e) forming a layer of gallium nitride material over a subsequent transition layer;
wherein at least one transition layer or subsequent transition layer comprises a layer of AlGaN and a layer of SiN.

17. A method according to claim 16, wherein steps d) and e) are repeated at least once.

18. A method according to claim 1, wherein the metal layer comprises Al.

19. A method according to claim 1, further comprising the step, intermediate steps a) and b), of forming an AlN layer over the metal layer.

20. A semiconductor template for producing a gallium nitride material, comprising a substrate with a metal layer formed over the substrate, and a transition layer formed over the substrate, the transition layer being compositionally graded such that the composition of the transition layer at a depth (z) thereof is a function f(z) of that depth;
wherein the Al compositional grading function f(z) of the transition layer has a profile including two plateaux at respective depths z1 and z2 where df(z1)/dz=df(z2)/dz=0, and wherein the function decreases continuously between z1 and z2.
